(19) United States
(12) Patent Application Publication
(10) Pub. No.: US 2019/0121189 A1
(43) Pub. Date: Apr. 25, 2019

(54) ACTIVE MATRIX SUBSTRATE AND PRODUCTION METHOD THEREFOR

(71) Applicant: SHARP KABUSHIKI KAISHA, Osaka (JP)

(72) Inventors: YOSHIHITO HARA, Sakai City (JP); HIDEKI KITAGAWA, Sakai City (JP); TOHRU DAITOH, Sakai City (JP); HAJIME IMAI, Sakai City (JP); MASAKI MAEDA, Sakai City (JP); TATSUYA KAWASAKI, Sakai City (JP); TOSHIKATSU ITOH, Sakai City (JP)

(21) Appl. No.: 16/169,899

(22) Filed: Oct. 24, 2018

(30) Foreign Application Priority Data
Oct. 24, 2017 (JP) 2017-205022

(51) Int. Cl. G02F 1/1343; H01L 27/12; G02F 1/1368; G02F 1/1362

(52) U.S. Cl. CPC G02F 1/13439; H01L 27/1225; H01L 27/124; G02F 1/134363; H01L 29/7869; G02F 1/136286; H01L 27/1262; H01L 27/127; G02F 1/1368

(57) ABSTRACT

An active matrix substrate includes source bus lines, gate bus lines, a thin-film transistor and a pixel electrode provided for each pixel region, a common electrode disposed on the pixel electrode with a dielectric layer interposed therebetween, and a spin-on-glass layer disposed, in a display region, between a gate metal layer and a source metal layer. The pixel electrode is formed of the same metal oxide film of which an oxide semiconductor layer of the thin-film transistor is formed. The spin-on-glass layer has an opening, in each pixel region, in a portion where the thin-film transistor is formed. At an intersection portion where one of the source bus lines and one of the gate bus lines intersect, the spin-on-glass layer is located between the source bus line and gate bus line. In each pixel region, the spin-on-glass layer is located between at least a portion of the pixel electrode and a substrate.

### BACKGROUND

### 1. Technical Field

The present invention relates to active matrix substrates having oxide semiconductor TFTs and production methods therefor.

### 2. Description of the Related Art

Active matrix substrates for use in liquid crystal display apparatuses, etc., include a switching element such as a thin-film transistor (hereinafter referred to as a “TFT”) for each pixel. As such a switching element, a TFT having an amorphous silicon film as an active layer (hereinafter referred to as an “amorphous silicon TFT”) and a TFT having a polycrystalline silicon film as an active layer (hereinafter referred to as a “polycrystalline silicon TFT”) have conventionally been widely used.

It has in recent years been proposed that oxide semiconductors may be used as a material for the active layer of a TFT instead of amorphous silicon and polycrystalline silicon. Such a TFT is referred to as an “oxide semiconductor TFT.” Oxide semiconductors have a higher mobility than that of amorphous silicon. Therefore, oxide semiconductor TFTs can be operated at higher speed than that of amorphous silicon TFTs. In addition, oxide semiconductor TFTs can be used to provide a higher-definition display panel than when amorphous silicon TFTs are used. An active matrix substrate (hereinafter referred to as a “TFT substrate”) that is produced using an oxide semiconductor may be mainly applied to small- and medium-sized liquid crystal panels for smartphones, etc.

A TFT substrate including an oxide semiconductor TFT is described in, for example, Japanese Laid-Open Patent Publication No. 2003-86808. For example, Japanese Laid-Open Patent Publication No. 2008-40343 describes integrally forming a semiconductor layer that is subsequently treated to form the active layer of a TFT, and a pixel electrode, by reducing the resistance of a portion of an oxide semiconductor film.

Meanwhile, for active-matrix liquid crystal display apparatuses, various operation modes have been proposed and employed according to applications thereof. Examples of the operation modes include the twisted nematic (TN) mode, vertical alignment (VA) mode, in-plane switching (IPS) mode, and fringe field switching (FFS) mode.

The TN and VA modes are a vertical field mode in which an electric field is applied to liquid crystal molecules in a liquid crystal layer using a pair of electrodes sandwiching the liquid crystal layer. The IPS and FFS modes are a horizontal field mode in which an electric field is applied to liquid crystal molecules in a direction parallel to a substrate surface (horizontal direction) using a pair of electrodes provided on one of two substrates. In the horizontal field technique, liquid crystal molecules are not erected from the substrate, and therefore, a wider viewing angle can be achieved than when the vertical field technique is used. In liquid crystal display apparatuses of the IPS mode, which is a horizontal field operation mode, a pair of comb electrodes is formed on a TFT substrate by patterning a metal film. Therefore, a problem arises that the transmittance and aperture ratio are low. In contrast to this, in liquid crystal display apparatuses of the FFS mode, the aperture ratio and transmittance can be improved by forming transparent electrodes on a TFT substrate.

### SUMMARY

The definition and resolution of large-sized liquid crystal panels for televisions, etc., have been increasing. To increase the definition and resolution, it is preferable to use oxide semiconductor TFT substrates.

However, conventional oxide semiconductor TFT substrates are mainly used for small- and medium-sized liquid crystal panels for mobile applications. The application of oxide semiconductor TFT substrates to large-sized, high-definition liquid crystal panels has not been fully explored. The present inventors have studied the production of a TFT substrate applicable to large-sized liquid crystal panels, to find a problem that the production process requires an increased number of photomasks, leading to an increase in manufacturing cost. This will be described in detail below.

One non-limiting, and exemplary embodiment provides an active matrix substrate applicable to large-sized liquid crystal panels, and a method for producing such an active matrix substrate at lower cost.

In one general aspect, an active matrix substrate disclosed herein having a display region including a plurality of pixel regions, and a non-display region that is different from the display region, includes a substrate, a plurality of source bus lines supported by the substrate and extending in a first direction, a plurality of gate bus lines supported by the substrate and extending in a second direction crossing the first direction, a thin-film transistor disposed in each of the plurality of pixel regions, a pixel electrode disposed in each of the plurality of pixel regions, a common electrode disposed on the pixel electrode with a dielectric layer interposed therebetween, and a spin-on-glass layer disposed, in the display region, between a gate metal layer including the plurality of gate bus lines, and a source metal layer including the plurality of source bus lines. In each of the plurality of pixel regions, the thin-film transistor has a gate electrode formed in the gate metal layer, a gate insulating layer covering the gate electrode, an oxide semiconductor layer disposed on the gate insulating layer, and a source electrode and a drain electrode formed in the source metal layer and electrically connected to the oxide semiconductor layer. The gate electrode is electrically connected to a corresponding one of the plurality of gate bus lines. The source electrode is electrically connected to a corresponding one of the plurality of source bus lines. The drain electrode is in contact with the pixel electrode. The pixel electrode is formed of a same metal oxide film of which the oxide semiconductor layer is formed. The spin-on-glass layer has an opening in a portion thereof in which the thin-film transistor is formed, in each of the plurality of pixel regions. At an intersection portion where the corresponding one of the plurality of source bus lines and the corresponding one of the plurality of gate bus lines intersect, the spin-on-glass layer is located between the corresponding one of the plurality of source bus lines and the corresponding one of the plurality of gate bus lines. In each of the plurality of pixel regions, the spin-on-glass layer is located between at least a portion of the pixel electrode and the substrate.

In one non-limiting, and exemplary embodiment, the pixel electrode and the oxide semiconductor layer are disposed apart from each other. The entire pixel electrode overlaps with the spin-on-glass layer as viewed in a normal direction of the substrate. The oxide semiconductor layer is located in the opening of the spin-on-glass layer.

In one non-limiting, and exemplary embodiment, the pixel electrode is continuous with the oxide semiconductor layer.

In one non-limiting, and exemplary embodiment, the active matrix substrate further includes an auxiliary metal interconnect in contact with the common electrode.

In one non-limiting, and exemplary embodiment, the active matrix substrate further includes an inorganic insulating layer disposed between the source metal layer and the dielectric layer. The pixel electrode includes a first portion that is in contact with the inorganic insulating layer, and a second portion that is in contact with the dielectric layer. The first portion is a semiconductor region, and the second portion is a low-resistance region having an electrical resistivity lower than that of the semiconductor region.

In one non-limiting, and exemplary embodiment, the dielectric layer contains silicon nitride, and the inorganic insulating layer contains silicon oxide.

In one non-limiting, and exemplary embodiment, the gate insulating layer includes a first insulating layer, and a second insulating layer disposed between the first insulating layer and the gate electrode. The spin-on-glass layer is disposed between the second insulating layer and the first insulating layer.

In one non-limiting, and exemplary embodiment, the drain electrode is in contact with upper surfaces of the oxide semiconductor layer and the pixel electrode.

In one non-limiting, and exemplary embodiment, the drain electrode is in contact with lower surfaces of the oxide semiconductor layer and the pixel electrode.

In one non-limiting, and exemplary embodiment, the oxide semiconductor layer contains an In—Ga—Zn—O semiconductor.

In one non-limiting, and exemplary embodiment, the In—Ga—Zn—C semiconductor includes a crystalline portion.

In one non-limiting, and exemplary embodiment, the oxide semiconductor layer of the thin-film transistor has a multilayer structure.

In one general aspect, a method disclosed herein for producing an active matrix substrate having a display region including a plurality of pixel regions, and a non-display region that is different from the display region, and including a thin-film transistor and a pixel electrode disposed in each of the plurality of pixel regions, includes (a) forming on the substrate, a gate metal layer including gate electrode of the thin-film transistor in each of the plurality of pixel regions and a plurality of gate bus lines, (b) forming a spin-on-glass layer by forming a spin-on-glass film on the gate metal layer, and forming, in each of the plurality of pixel regions, an opening in a portion of the spin-on-glass film where the thin-film transistor is subsequently formed, (c) forming a first insulating layer on the spin-on-glass layer, (d) forming an oxide semiconductor film on the first insulating layer and patterning the oxide semiconductor film so as to form an active-layer-forming oxide semiconductor layer to become an active layer of the thin-film transistor, and to form a pixel-electrode-forming oxide semiconductor layer to become the pixel electrode, wherein the active-layer-forming oxide semiconductor layer is disposed so that, in the opening of the spin-on-glass layer, at least a portion thereof overlaps with the gate electrode with the first insulating layer interposed therebetween, and the pixel-electrode-forming oxide semiconductor layer is disposed on the spin-on-glass layer with the first insulating layer interposed therebetween; (e) forming a source metal layer including source electrode and drain electrode of the thin-film transistor in each of the plurality of pixel regions and a plurality of source bus lines, wherein the source electrode is in contact with the active-layer-forming oxide semiconductor layer, and the drain electrode is in contact with the active-layer-forming oxide semiconductor layer and the pixel-electrode-forming oxide semiconductor layer, (f) forming an inorganic insulating layer covering the active-layer-forming oxide semiconductor layer, the pixel-electrode-forming oxide semiconductor layer, the source electrode, and the drain electrode, and forming, in the inorganic insulating layer, a pixel opening through which a portion of the pixel-electrode-forming oxide semiconductor layer is exposed (g) forming a dielectric layer having ability to reduce an oxide semiconductor contained in the pixel-electrode-forming oxide semiconductor layer, on the inorganic insulating layer and in the pixel opening, wherein the resistance of a portion of the pixel-electrode-forming oxide semiconductor layer that is in contact with the dielectric layer in each of the pixel opening is reduced so that the portion forms a low-resistance region functioning as the pixel electrode, and a portion of the pixel-electrode-forming oxide semiconductor layer that is covered by the inorganic insulating layer remains as a semiconductor region, and (h) forming a common electrode on the dielectric layer.

In one non-limiting, and exemplary embodiment, in step (d), the active-layer-forming oxide semiconductor layer and the pixel-electrode-forming oxide semiconductor layer are spaced apart from each other, the entire active-layer-forming oxide semiconductor layer is located in the opening of the spin-on-glass layer, and the entire pixel-electrode-forming oxide semiconductor layer is disposed on the spin-on-glass layer with the first insulating layer interposed therebetween.

In one non-limiting, and exemplary embodiment, the method further includes forming an auxiliary metal interconnect that is in contact with the common electrode.

In one non-limiting, and exemplary embodiment, the oxide semiconductor film contains an In—Ga—Zn—O semiconductor.

In one non-limiting, and exemplary embodiment, the In—Ga—Zn—O semiconductor includes a crystalline portion.

In one non-limiting, and exemplary embodiment, the oxide semiconductor film has a multilayer structure.

According to the above aspects, provided are an active matrix substrate applicable to large-sized liquid crystal panels, and a method capable of producing such an active matrix substrate at lower cost.

### BRIEF DESCRIPTION OF THE DRAWINGS

FIG. 1 is a diagram schematically showing an example structure of a TFT substrate 100 according to an embodiment of the present invention.

FIGS. 2A and 2B are plan views showing examples of each pixel region P and S-G connection portion Csg of the TFT substrate 100.

FIG. 3 is a cross-sectional view showing examples of the pixel region P, the S-G connection portion Csg, an S-G intersection portion Dsg, and a terminal T.

FIG. 4A is a cross-sectional view for describing steps in a production method for the TFT substrate 100.

FIG. 4B is a cross-sectional view for describing steps in the production method for the TFT substrate 100.

FIG. 4C is a cross-sectional view for describing steps in the production method for the TFT substrate 100.

FIG. 4D is a cross-sectional view for describing steps in the production method for the TFT substrate 100.

FIG. 4E is a cross-sectional view for describing steps in the production method for the TFT substrate 100.

FIG. 4F is a cross-sectional view for describing steps in the production method for the TFT substrate 100.

FIG. 4G is a cross-sectional view for describing steps in the production method for the TFT substrate 100.

FIG. 5 is a diagram schematically showing a production process of the TFT substrate 100.

FIG. 6 is a cross-sectional view showing a pixel region P in another TFT substrate 101 according to the embodiment of the present invention.

FIG. 7 is a cross-sectional view showing a pixel region P in another TFT substrate 102 according to the embodiment of the present invention.

### DETAILED DESCRIPTION

### First Embodiment

A first embodiment of a TFT substrate according to the present invention will now be described with reference to the accompanying drawings. Here, a TFT substrate for use in an FFS-mode liquid crystal display apparatus will be described as an example. The FFS mode is a horizontal field mode in which a pair of electrodes (a pixel electrode PE and a common electrode CE) is provided on one of two substrates, and an electric field is applied to liquid crystal molecules in a direction parallel to the substrate surface (horizontal direction). Note that the TFT substrate of this embodiment is widely applicable to liquid crystal display apparatuses having other operation modes, various display apparatuses other than liquid crystal display apparatuses, electronic apparatuses, etc.

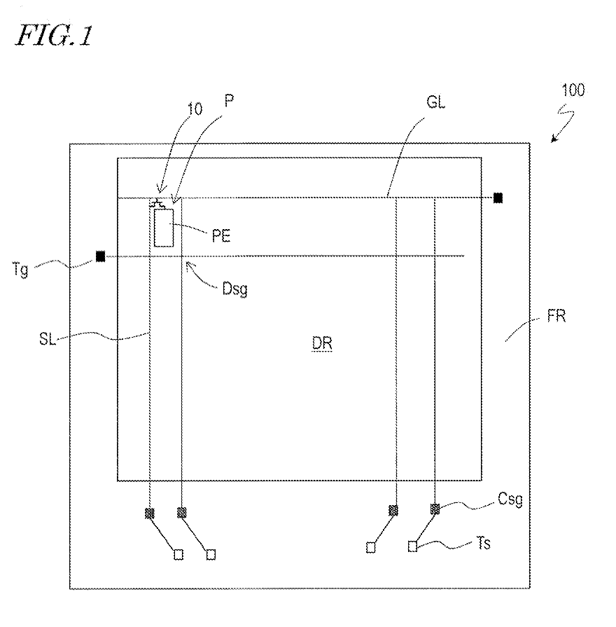

FIG. 1 is a diagram schematically showing an example structure of the TFT substrate 100 of this embodiment as viewed from above. The TFT substrate 100 has a display region DR responsible for displaying, and a peripheral region (frame region) FR located outside the display region DR.

In the display region DR, provided are a plurality of source bus line SL extending in a first direction, and a plurality of gate bus lines GL extending in a second direction crossing the first direction. Each region surrounded by these bus lines serves as a “pixel region P.” The pixel regions P (may also be referred to as “pixels”) are a region corresponding to a pixel of the display apparatus. The pixel regions P are arranged in a matrix. In each pixel region P, a pixel electrode PE and a thin-film transistor (TFT) 10 are provided. The gate electrode and source electrode of each TFT 10 are electrically connected to the corresponding gate bus line GL and source bus line SL, respectively. The drain electrode of each TFT 10 is electrically connected to the corresponding pixel electrode PE. In this embodiment, a common electrode (not shown) is provided above the pixel electrode PE, facing the pixel electrode PE with a dielectric layer (insulating layer) interposed therebetween.

In each pixel region P, the TFT 10 is typically located in the vicinity of a portion Dsg where the source bus line SL and the gate bus line GL intersect with an insulating film interposed therebetween. The portion Dsg where an interconnect in a source metal layer such as the source bus line SL and an interconnect in a gate metal layer such as the gate bus line GL intersect with an insulating film interposed therebetween is herein referred to as an “S-G intersection portion.”

In the peripheral region FR, provided are a plurality of gate terminals Tg, a plurality of source terminals Ts, a plurality of S-G connection portions Csg, etc. Although not shown, drive circuits such as a gate driver may be monolithically formed in the peripheral region FR. Alternatively, drive circuits may be mounted in the peripheral region FR.

Each gate terminal Tg is connected to the corresponding gate bus line GL, and each source terminal Ts is connected to the corresponding source bus line SL.

The S-G connection portions Csg connect a layer (source metal layer) that is formed of the same conductive film of which the source bus lines SL is formed, and a layer (gate metal layer) that is formed of the same conductive film of which the gate bus lines GL is formed. For example, each S-G connection portion Csg may be provided between the corresponding source bus line SL and source terminal Ts, to connect the source bus line SL to an interconnect in the gate metal layer. In this case, the interconnect in the gate metal layer is connected to an external interconnect at the source terminal Ts. In other words, the source terminal Ts has substantially the same structure as that of the gate terminal Tg.

Next, each region of the TFT substrate 100 of this embodiment will be described in greater detail.

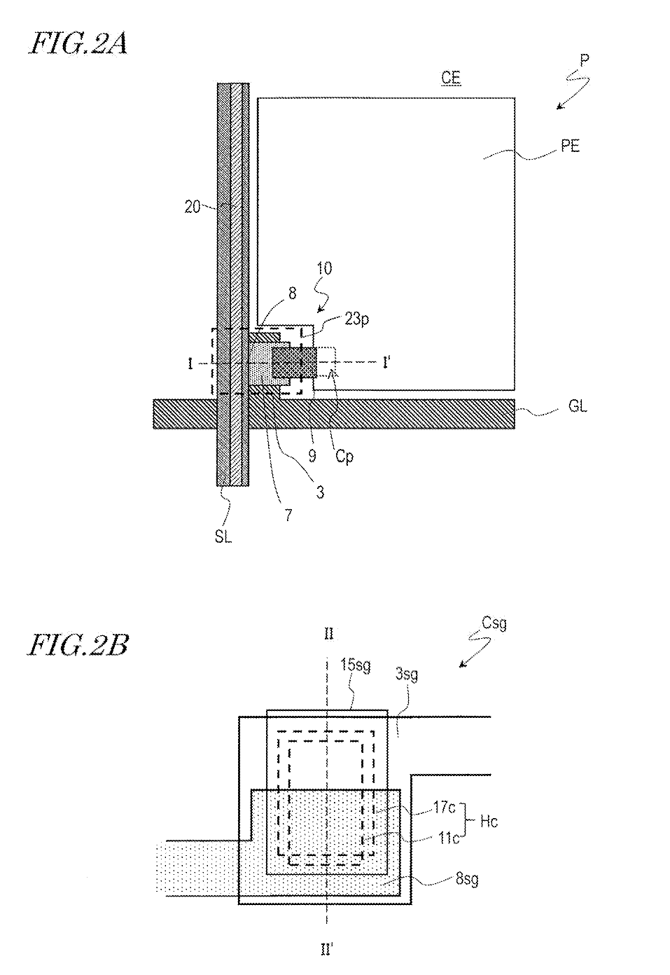

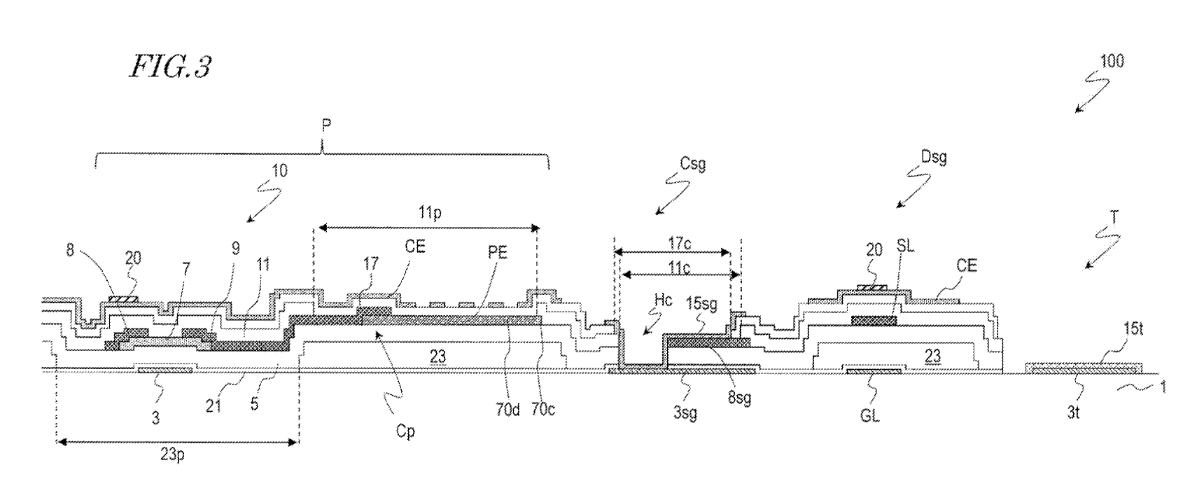

FIGS. 2A and 2B are plan views showing examples of each pixel region P and S-G connection portion Csg of the TFT substrate 100. FIG. 3 is a cross-sectional view showing examples of the pixel region P, the S-G connection portion Csg, the S-G intersection portion Dsg, and the terminal T. The terminal T is the source terminal Ts or the gate terminal Tg of FIG. 1.

The pixel region P is surrounded by the source bus line SL, and the gate bus line GL extending in a direction crossing the source bus line SL. The pixel region P has a substrate 1, the TFT 10 supported by the substrate 1, the pixel electrode PE, and the common electrode CE.

The TFT 10 is, for example, a channel etch-type bottom-gate structure TFT. The TFT 10 includes a gate electrode 3 disposed on the substrate 1, a gate insulating layer covering the gate electrode 3, an oxide semiconductor layer 7 disposed on the gate insulating layer, and a source electrode 8 and a drain electrode 9 that are electrically connected to the oxide semiconductor layer 7. In this example, the gate insulating layer includes a first insulating layer 5, and a second insulating layer 21 that is disposed between the first insulating layer 5 and the gate electrode 3, and functions as a cap layer. Note that the second insulating layer 21 may not be provided.

The semiconductor layer 7 is in the shape of, for example, an island, and is disposed on the first insulating layer 5 so as to overlap the gate electrode 3 with the gate insulating layer interposed therebetween. The source electrode 8 and the drain electrode 9 are each disposed in contact with a portion of an upper surface of the semiconductor layer 7. A portion of the semiconductor layer 7 that is in contact with the source electrode 8 is referred to as a “source contact region,” and a portion of the semiconductor layer 7 that is in contact with the drain electrode 9 is referred to as a “drain contact region.” A portion of the semiconductor layer 7 that is located between the source contact region and the drain contact region and overlaps with the gate electrode 3 as viewed in the normal direction of the substrate 1, is referred to as a “channel region.”

The gate electrode 3 is connected to the corresponding gate bus line GL, and the source electrode 8 is connected to the corresponding source bus line SL. The drain electrode 9 is electrically connected to the pixel electrode PE. The gate electrode 3 and the gate bus line GL may be integrally formed using the same conductive film. The source electrode 8 and the source bus line SL may also be integrally formed using the same conductive film. The gate electrode 3 and the source electrode 8 may be portions of the gate bus line GL and the source bus line SL, respectively, or portions protruding from the gate bus line GL and the source bus line SL, respectively. In this example, the source bus line SL, the source electrode 8, and the drain electrode 9 are disposed in the source metal layer (i.e., formed of the same conductive film of which the source bus line SL is formed).

The TFT 10 is covered by an interlayer insulating layer 11. The interlayer insulating layer 11 is, for example, an inorganic insulating layer (passivation film). The interlayer insulating layer 11 may not include a planarization film that is an organic insulating layer, etc. As shown in FIG. 3, the TFT 10 may be covered by the interlayer insulating layer 11, a dielectric layer 17 extended on the interlayer insulating layer 11, and the common electrode CE disposed on the dielectric layer 17.

The pixel electrode PE and the common electrode CE are disposed to overlap each other with the dielectric layer 17 interposed therebetween. A separate pixel electrode PE is provided for each pixel. A single common electrode CE may be shared by pixels.

In this embodiment, the pixel electrode PE is formed of the same metal oxide film of which the oxide semiconductor layer 7 is formed. Therefore, the pixel electrode PE and the oxide semiconductor layer 7 may have the same composition and substantially the same thickness. The pixel electrode PE may, for example, be formed by reducing the resistance of a portion of the oxide semiconductor film. In this example, a portion of the pixel electrode PE that is covered by the interlayer insulating layer 11 is a semiconductor region 70s, and a portion of the pixel electrode PE that is in contact with the drain electrode 9 or the dielectric layer 17 is a low-resistance region (conductive material region) 70d that has an electrical resistivity lower than that of the semiconductor region 70s. The electrical resistivity of the semiconductor region 70s is, for example, substantially the same as that of the channel region of the oxide semiconductor layer 7. A portion of the pixel electrode PE is in contact with the drain electrode 9, and is electrically connected to the oxide semiconductor layer 7 through the drain electrode 9. A portion Cp where the pixel electrode PE is in contact with the drain electrode 9 is referred to as a “pixel contact portion.” In this example, the oxide semiconductor layer 7 and the pixel electrode PE are disposed apart from each other. The drain electrode 9 is in contact with an upper surface and side surface of the pixel electrode PE at the pixel contact portion Cp. As described below, the oxide semiconductor layer 7 and the pixel electrode PE may be continuous with each other (see FIG. 6).

The common electrode CE has at least one slit or notch for each pixel. The common electrode CE may be formed throughout the pixel region P. The common electrode CE may be formed using a transparent conductive film, such as an indium tin oxide (ITO) film, indium zinc oxide (In—Zn—O) film, or zinc oxide (ZnO) film.

In the case where the TFT substrate 100 is applied to a large-sized liquid crystal panel, an auxiliary metal interconnect 20 that has an electrical resistance smaller than that of the common electrode CE may be disposed in contact with the common electrode CE. The auxiliary metal interconnect 20 may, for example, be extended along the source bus line SL, overlapping with the source bus line SL as viewed in the normal direction of the substrate 1. As a result, the electrical resistance of the common electrode CE combined with the auxiliary metal interconnect 20 can be caused to be smaller than the electrical resistance of the common electrode CE alone, without a reduction in pixel aperture ratio. Therefore, variations in a voltage applied to the liquid crystal layer of each pixel in the panel surface through the common electrode CE can be reduced.

Furthermore, in this embodiment, a spin-on-glass (SOG) layer 23 is disposed between the gate metal layer, and the source metal layer and the oxide semiconductor layer 7. The SOG layer 23 may be disposed between the gate metal layer and the gate insulating layer. In this example, the SOG layer 23 is disposed between the second insulating layer 21 and the first insulating layer 5. The SOG layer 23 is a coating-type SiO₂ film. The SOG layer 23, which is relatively thick (thickness: for example, 1-3 μm), may also function as a planarization film.

The SOG layer 23 covers substantially the entirety of each pixel region P, and has an opening 23p (indicated by a dashed line in FIG. 2A) in a region where the TFT 10 is formed (TFT-formed region). The SOG layer 23 may be continuous between adjacent pixel regions P. Specifically, the SOG layer 23 may be provided throughout the display region DR, and have a plurality of openings 23p corresponding to the respective TFT-formed regions. The SOG layer 23 that is disposed between the gate metal layer and the source metal layer can reduce overlap capacitances of the S-G connection portion Csg and the S-G intersection portion Dsg.

In the pixel region P, the SOG layer 23 is located between at least a portion of the pixel electrode PE and the substrate 1. The SOG layer 23 can form a planarized region, on which the pixel electrode PE and the common electrode CE are formed. Therefore, variations in the thickness of a liquid crystal layer disposed between these electrodes and a counter substrate (not shown) can be prevented or reduced. Although an organic insulating layer is conventionally provided as a planarization layer between the source metal layer and the pixel electrode, such a planarization film may not be provided on the source metal layer in this embodiment. As shown in FIG. 3, the pixel electrode PE may be disposed on the SOG layer 23 with the interlayer insulating layer 11 interposed therebetween. As viewed in the normal direction of the substrate 1, the entire pixel electrode PE overlaps with the SOG layer 23, and the entirety of the oxide semiconductor layer 7 may be located in the opening 23p of the SOG layer 23.

The S-G connection portion Csg has a gate connection portion 3sg formed in the gate metal layer (formed of the same conductive film of which the gate bus line GL is formed), a source connection portion 8sg formed in the source metal layer, and a transparent connection portion 15sg formed of the same transparent conductive film of which the common electrode CE is formed. The gate connection portion 3sg and the source connection portion 8sg are electrically connected to each other by the transparent connection portion 15sg. The source connection portion 8sg may be an end of the source bus line SL, and the gate connection portion 3sg may be an interconnect (gate interconnect) connecting the source bus line SL and the source terminal Ts together.

In this example, the S-G connection portion Csg has a contact hole Hc through which at least a portion of the gate connection portion 3sg and at least a portion of the source connection portion 8sg are exposed, in the second insulating layer 21, the first insulating layer 5, the interlayer insulating layer 11, and the dielectric layer 17. The transparent connection portion 15sg is disposed on the dielectric layer 17 and in the contact hole Hc, and is in contact with the source connection portion 8sg and the gate connection portion 3sg through the contact hole Hc. In the S-G connection portion forming region that is a non-display region, the SOG layer 23 is not provided.

Here, the contact hole Hc has a first opening 11c that is formed in the second insulating layer 21, the first insulating layer 5, and the interlayer insulating layer 11, and through which at least a portion of the gate connection portion 3sg is exposed, and a second opening 17c that is formed in the dielectric layer 17, and through which at least a portion of the source connection portion 8sg is exposed. The first opening 11c and the second opening 17c at least partly overlap with each other to form one contact hole Hc.

In the S-G intersection portion Dsg, the SOG layer 23 is disposed between the gate metal layer and the source metal layer. In the example of FIG. 3, in each pixel region P, the source bus line SL and the gate bus line GL intersect at the S-G intersection portion Dsg. The common electrode CE is disposed over the source bus line SL with the interlayer insulating layer 11 and the dielectric layer 17 interposed therebetween. The auxiliary metal interconnect 20 is disposed on the common electrode CE so as to overlap with the source bus line SL. Because the relatively thick 50G layer 23 is disposed between the source bus line SL and the gate bus line GL, a capacitance formed by the source bus line SL, the gate bus line GL, and an insulating film interposed therebetween can be reduced.

The terminals T each have a lower conductive portion 3t disposed on the substrate 1, and an island-shaped upper conductive portion 15t covering the lower conductive portion 3t. The lower conductive portion 3t is formed in the gate metal layer. The lower conductive portion 3t may, for example, be the gate bus line GL, or the above gate interconnect. The upper conductive portion 15t may be formed of the same transparent conductive film of which the common electrode CE is formed. In the terminal forming regions where the terminals are formed, the SOG layer 23 is not provided.

The TFT substrate 100 of this embodiment has the following advantages.

As the size and definition of a liquid crystal panel increase, it is necessary to further reduce a gate-source parasitic capacitance (overlap capacitance) of the TFT substrate. In contrast to this, in the TFT substrate 100 of this embodiment, the SOG layer 23 is provided between the gate metal layer and the source metal layer, and therefore, the gate-source overlap capacitance can be reduced.

Large-sized liquid crystal panels are also accompanied by the problem that there are significant variations in a voltage applied by the common electrode CE in the panel surface. In contrast to this, in this embodiment, the auxiliary metal interconnect 20 is disposed in contact with the common electrode CE, and therefore, variations in a voltage applied by the common electrode CE in the panel surface can be reduced.

Therefore, the TFT substrate 100 can be preferably applied to liquid crystal panels having high resolutions (e.g., 8K or more) and large sizes (e.g., 60 inches or more).

In the TFT substrate 100, the oxide semiconductor layer 7 and the pixel electrode PE are formed using the same metal oxide film. As a result, the production process can be simplified as described below. The oxide semiconductor layer 7 and the pixel electrode PE may be spaced apart from each other or may be continuous with each other.

In the TFT substrate 100 of FIG. 2A, the oxide semiconductor layer 7 and the pixel electrode PE are spaced apart from each other. As shown in FIG. 2A, the oxide semiconductor layer 7 may be disposed only in the opening 23p of the SOG layer 23, and the pixel electrode PE may be disposed only above the SOG layer 23 (only in a region that covers the SOG layer 23 as viewed in the normal direction of the substrate 1). In this embodiment, the thickness of the metal oxide film for forming the oxide semiconductor layer 7 and the pixel electrode PE is limited so that desired TFT characteristics are achieved. For example, the thickness of the metal oxide film is limited to 100 nm or less. Therefore, in the case where the oxide semiconductor layer 7, which is located in the opening 23p of the SOG layer 23, is continuous with the pixel electrode PE, which is disposed above the SOG layer 23 (i.e., the oxide semiconductor layer 7 and the pixel electrode PE are integrally formed), it may be difficult to form the metal oxide film continuously at a step portion of the relatively thick SOG layer 23. In contrast to this, in the case where the oxide semiconductor layer 7 and the pixel electrode PE are disposed apart from each other as shown in FIG. 2A, it is not necessary to form the metal oxide film continuously at the step portion of the relatively thick SOG layer 23, and therefore, the discontinuation of the metal oxide film can be prevented or reduced. In addition, the metal oxide film can be patterned with higher accuracy.

In addition, according to this embodiment, the TFT substrate 100, which is applicable to large-sized liquid crystal panels, can be produced at lower cost, due to a reduction in the number of photomasks that are used in the production process. Large-sized liquid crystal panels conventionally have included an amorphous silicon TFT and have been of the VA mode. A TFT substrate for use in such a large-sized liquid crystal panel has been produced using, for example, five photomasks. This production process is referred to as a “basic process.” The present inventors have found that in the case where the FFS mode is employed in order to reduce or prevent a reduction in pixel aperture ratio accompanying an increase in definition of a liquid crystal panel, the number of photomasks that are used in the production of an FES-mode TFT substrate is greater than that of the basic process by two. If the common electrode is further provided with an auxiliary metal interconnect and an SOG film, two more photomasks are required. Therefore, the total number of photomasks that are required to produce the TFT substrate is nine. In contrast to this, in this embodiment, the pixel electrode PE is formed using the same metal oxide film of which the oxide semiconductor layer 7 is formed, and therefore, it is not necessary to use a separate photomask for patterning to form the pixel electrode PE. As a result, as described below, the number of photomasks that are used in the production of the TFT substrate can be reduced to eight. Therefore, the TFT substrate 100, that is applicable to high-definition, large-sized liquid crystal panels, can be produced at lower manufacturing cost.

It has also conventionally been necessary to provide a contact hole for connecting a pixel electrode and the drain electrode of a TFT together. In contrast to this, in this embodiment, the pixel electrode PE and the oxide semiconductor layer 7 are disposed in the same layer. Therefore, it is not necessary to provide a contact hole in the contact portion (pixel contact portion) Cp between the pixel electrode PE and the drain electrode 9. As a result, the pixel aperture ratio can be further improved.

<Production Method for TFT Substrate 100>

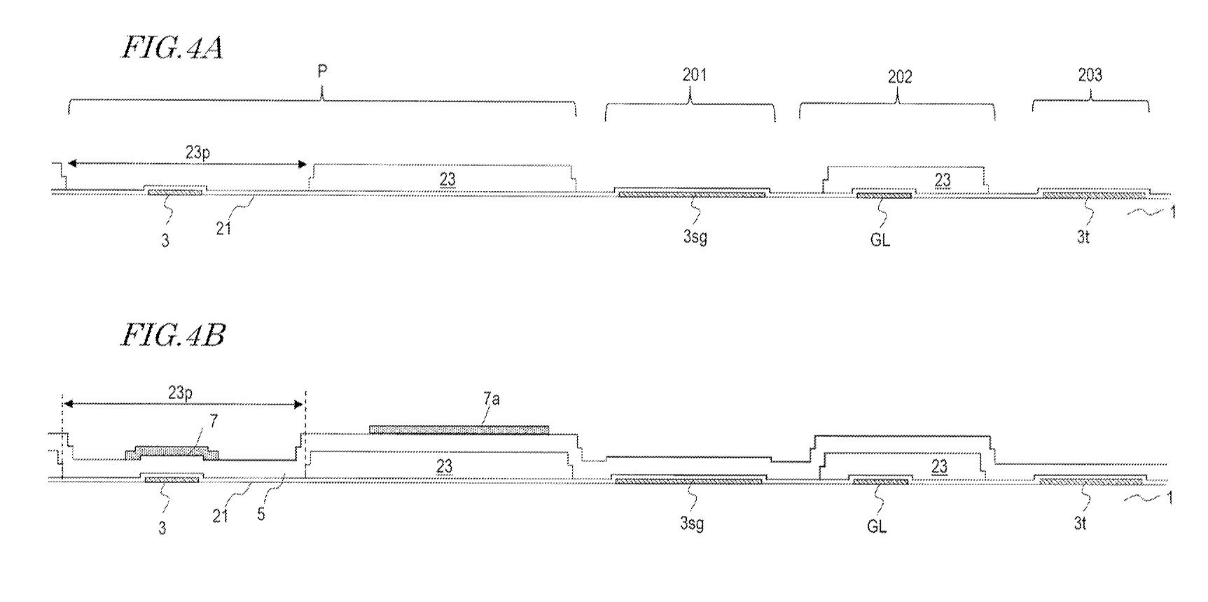

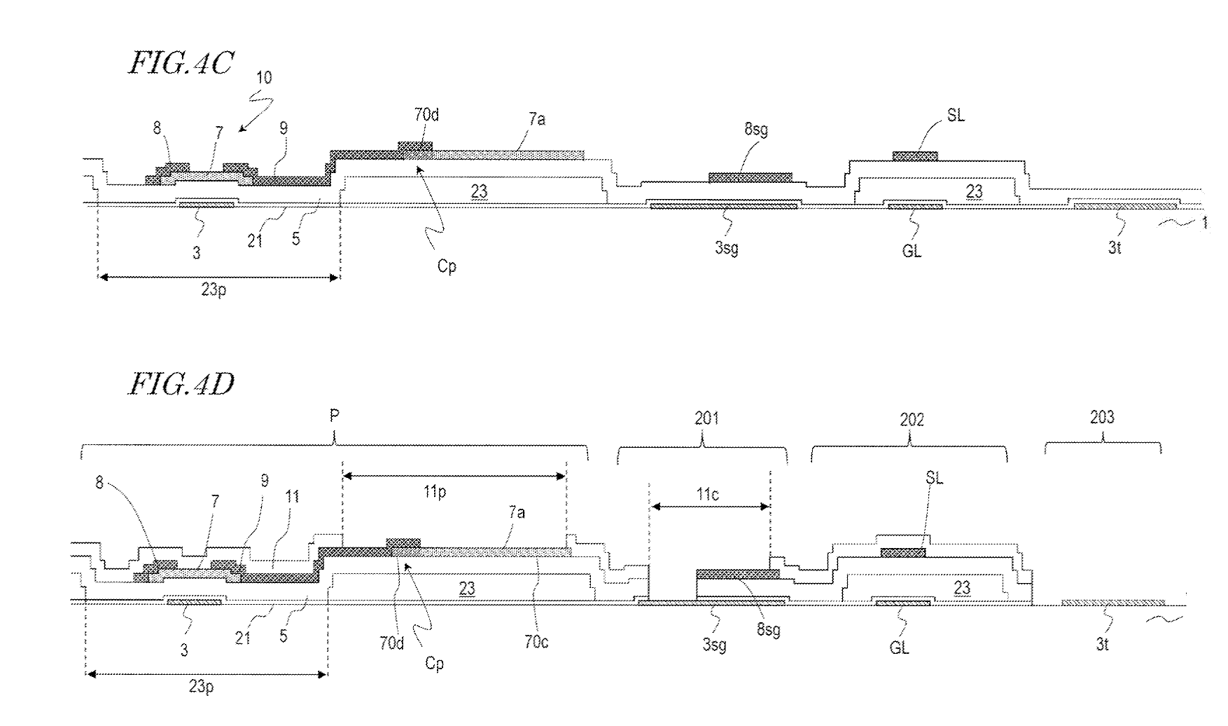

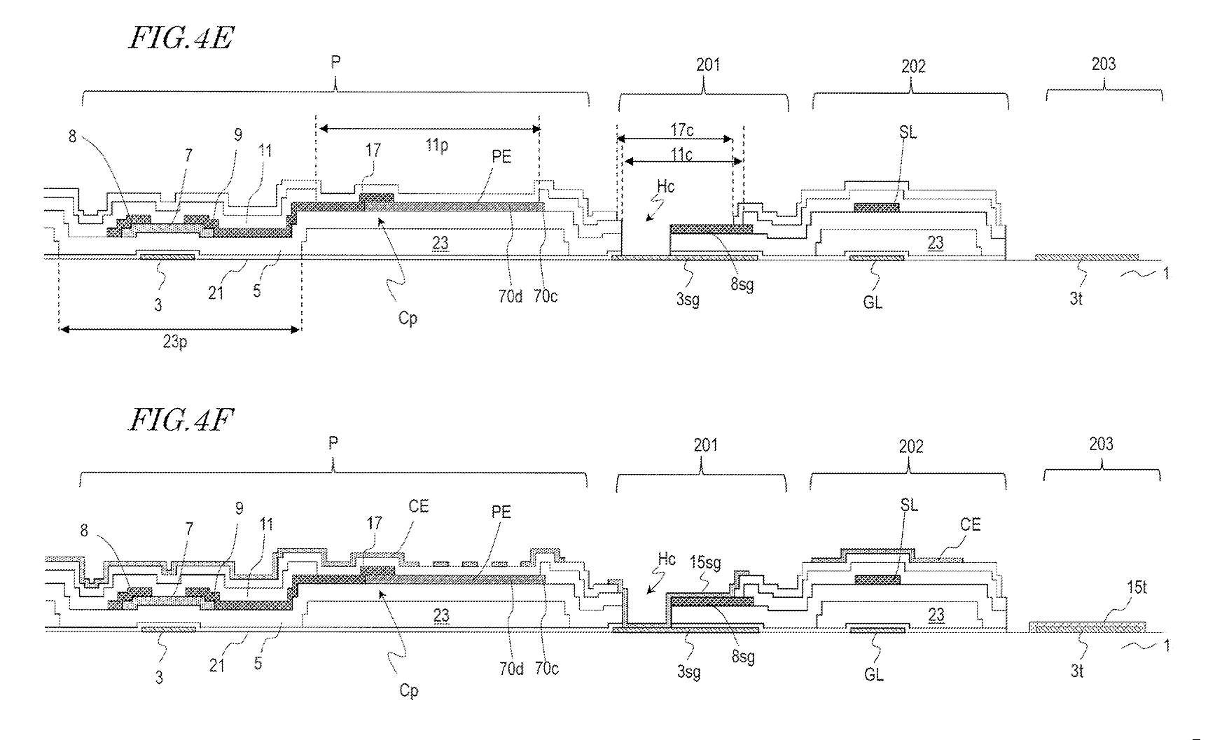

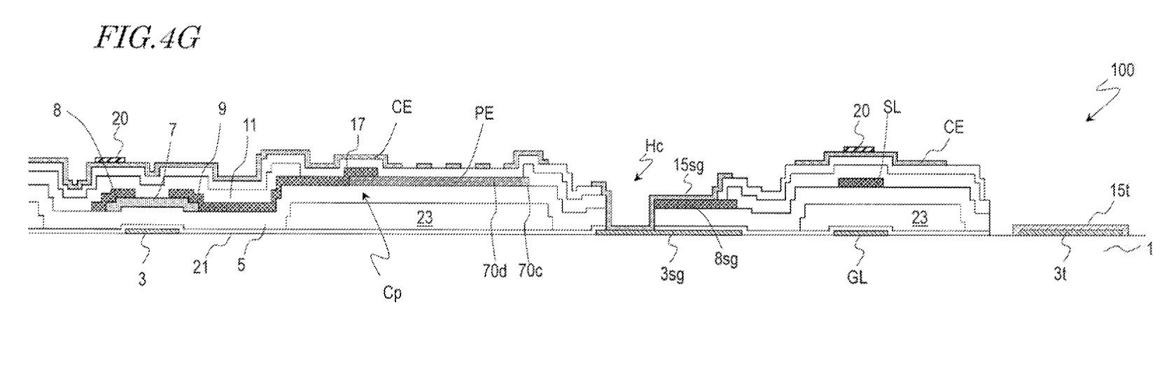

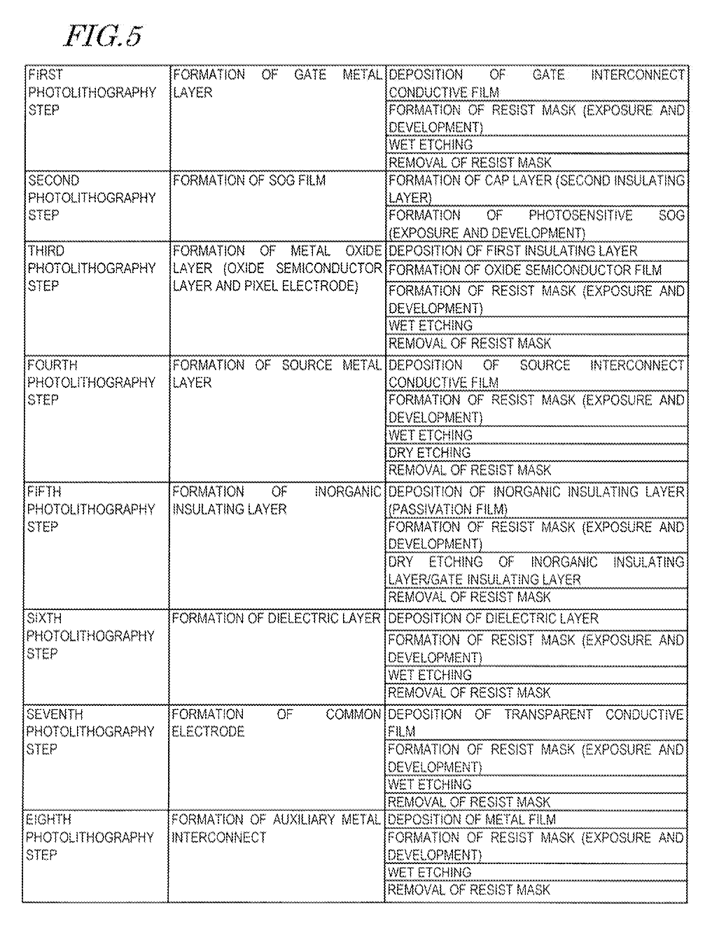

Next, an example production method for the TFT substrate 100 of this embodiment will be described with reference to FIGS. 4A-4G and 5. FIGS. 4A-4G are cross-sectional views for describing steps in a production method for the TFT substrate 100, showing a pixel region P, an S-G connection portion forming region 201, an S-G-intersection portion forming region 202, and a terminal forming region 203. FIG. 5 is a diagram schematically showing a production process of the TFT substrate 100.

Initially, as shown in FIG. 4A, a gate metal film is formed on the substrate 1, and thereafter, is patterned by a known photolithography process (first photolithography step). As a result, formed is a gate metal layer including the gate electrode 3, the gate connection portion 3sg, the lower conductive portion 3t, and the gate bus line GL.

As the substrate 1, a transparent insulating substrate can be used. Here, a glass substrate is used.

Examples of a material for the gate electrode film include, but are not particularly limited, metals such as aluminum (Al), tungsten (W), molybdenum (Mo), tantalum (Ta), chromium (Cr), titanium (Ti), and copper (Cu) or alloys thereof. Films containing these materials can be used as appropriate. A multilayer film including these films may also be used. Here, as the gate electrode film, a Cu film (thickness: for example, 500 nm) is used. The Cu film is patterned by, for example, wet etching.

Next, the second insulating layer 21 is formed as a cap layer to cover the gate metal layer. Thereafter, the SOG layer 23 is formed on a portion of the second insulating layer 21.

The second insulating layer 21 is, for example, a silicon nitride (SiNₓ) layer (thickness: for example, 50 nm).

The SOG layer 23 is formed by, for example, applying a photosensitive SOG film (thickness: for example, 1-3 μm) to the second insulating layer 21. Thereafter, the opening 23p through which the second insulating layer 21 is exposed is formed in the SOG layer 23 by exposure and development (second photolithography step). Here, the SOG layer 23 having a plurality of openings 23p in the display region is obtained. A portion of the SOG layer 23 that is located in the non-display region may be removed.

Next, as shown in FIG. 4B, the first insulating layer 5 is formed on the second insulating layer 21 and the SOG layer 23. Thereafter, an oxide semiconductor layer (also referred to as an “active-layer-forming oxide semiconductor layer”) 7 that is subsequently treated to form the active layer of the TFT, and a pixel-electrode-forming oxide semiconductor layer 7a that is subsequently treated to form a pixel electrode, are formed on the first insulating layer 5.

As the first insulating layer 5, used is a multilayer film including a silicon oxide (SiO₁) layer (thickness: 10-100 nm) as an upper layer, and a silicon nitride (SiNₓ) layer (thickness: for example, 50-500 nm) as a lower layer, for example.

The oxide semiconductor layer 7 and the pixel-electrode-forming oxide semiconductor layer 7a are obtained by forming an oxide semiconductor film on the first insulating layer 5 by, for example, sputtering, and patterning the oxide semiconductor film by a known photolithography process (third photolithography step). Here, as the oxide semiconductor film, an In—Ga—Zn—O semiconductor film (thickness: 5-200 nm) is used, for example. The patterning is performed by wet etching.

Here, the oxide semiconductor layer 7 is disposed so that, in the opening 23p of the SOG layer 23, at least a portion thereof overlaps with the gate electrode 3 with the first insulating layer 5 interposed therebetween. The oxide semiconductor layer 7 may be entirely located in the opening 23p of the SOG layer 23. Meanwhile, at least a portion of the pixel-electrode-forming oxide semiconductor layer 7a is disposed on the SOG layer 23 with the first insulating layer 5 interposed therebetween. The pixel-electrode-forming oxide semiconductor layer 7a may be entirely disposed on the SOG layer 23 with the first insulating layer 5 interposed therebetween.

Next, as shown in FIG. 4C, a source electrode film is formed to cover the oxide semiconductor layer 7, the pixel-electrode-forming oxide semiconductor layer 7a, and the first insulating layer 5 by, for example, sputtering. Thereafter, the source electrode film is patterned by a known photolithography process (fourth photolithography step) to form a source metal layer including the source electrode 8, the drain electrode 9, the source connection portion 8sg, and the source bus line SL. The patterning is performed by wet etching. Thereafter, dry etching may be performed. The source electrode 8 is disposed in contact with the oxide semiconductor layer 7. The drain electrode 9 is disposed in contact with the oxide semiconductor layer 7 and the pixel-electrode-forming oxide semiconductor layer 7a. The drain electrode 9 is disposed in contact with only a portion of the pixel-electrode-forming oxide semiconductor layer 7a. The resistance of the portion of the pixel-electrode-forming oxide semiconductor layer 7a that is in contact with the drain electrode 9 is reduced so that a low-resistance region 70d is formed. Thus, the TFT 10 is formed.

Examples of a material for the source electrode film include, but are not particularly limited, metals such as aluminum (Al), tungsten (W), molybdenum (Mo), tantalum (Ta), copper (Cu), chromium (Cr), and titanium (Ti) or alloys thereof, and nitrides of the metals. The films containing these materials can be used as appropriate. Here, as the source electrode film, a Cu film (thickness: for example, 500 nm) is used.

Next, as shown in FIG. 4D, the interlayer insulating layer 11 is formed to cover the source metal layer and the oxide semiconductor layers 7 and 7a.

As the interlayer insulating layer 11, an inorganic insulating layer such as a SiO₂ layer can be used, for example. The thickness of the interlayer insulating layer 11 is not particularly limited. For example, the interlayer insulating layer 11 that has a thickness of 400 nm or more can reliably function as a mask in the resistance reduction process. Meanwhile, the interlayer insulating layer 11 preferably has a thickness of 600 nm or less for a space-saving TFT substrate. Thereafter, the interlayer insulating layer 11, the first insulating layer 5, and the second insulating layer 21 are etched (also referred to as “PAS1/GI simultaneous etching”) (fifth photolithography step). Here, a pixel opening 11p through which at least a portion of the pixel-electrode-forming oxide semiconductor layer 7a is exposed is formed in the interlayer insulating layer 11, and the first opening 11c through which the gate connection portion 3sg and the source connection portion 8sg are exposed is formed in the interlayer insulating layer 11, the first insulating layer 5, and the second insulating layer 21, in the S-G connection portion forming region 201. At this time, the source connection portion 8sg functions as an etch stop, and therefore, a portion of the gate insulating layer that is covered by the source connection portion 8sg is not removed. In addition, in the terminal forming region 203, the interlayer insulating layer 11, the first insulating layer 5, and the second insulating layer 21 are removed so that the lower conductive portion 3t is exposed.

Next, as shown in FIG. 4E, the dielectric layer 17 is formed on the interlayer insulating layer 11 and in the opening 11c by, for example, CVD. As the dielectric layer 17, used is a reducing insulating film (e.g., a SiNₓ film) that has the ability to reduce an oxide semiconductor contained in the oxide semiconductor layers 7 and 7a. As a result, the resistance of a portion (in contact with the dielectric layer 17) of the pixel-electrode-forming oxide semiconductor layer 7a is reduced, so that the portion is changed to the low-resistance region 70d. The resistance of a portion of the oxide semiconductor layer 7 that is covered by the interlayer insulating layer 11, and is not in contact with the dielectric layer 17, is not reduced, so that the portion remains unchanged and serves as the semiconductor region 70s. Thus, the pixel electrode PE including the semiconductor region 70s and the low-resistance region 70d is obtained. Thereafter, the second opening 17c through which the gate connection portion 3sg and the source connection portion 8sg are exposed is formed in the dielectric layer 17 in the S-G connection portion forming region 201 by a known photolithography process (sixth photolithography step). As a result, the contact holes Hc including the openings 11c and 17c are obtained. In the terminal forming region 203, the dielectric layer 17 is removed so that the lower conductive portion 3t is exposed.

As the dielectric layer 17, a reducing insulating film can be used, such as a silicon nitride (SiNₓ) film, silicon oxynitride (SiOₓN_{y}; x>y) film, or silicon nitroxide (SiNₓO_{y}; x>y) film. The dielectric layer 17 also serves as a capacitive insulating film that forms an auxiliary capacitance. Therefore, the material and thickness of the dielectric layer 17 are preferably selected as appropriate so that the dielectric layer 17 has a predetermined capacitance CCS. SiNₓ may be preferably used in terms of dielectric constant and insulating properties. The dielectric layer 17 has a thickness of, for example, 70-180 nm.

Next, as shown in FIG. 4F, a transparent conductive layer including the common electrode CE, the transparent connection portion 15sg, and the upper conductive portion 15t are formed. Initially, a transparent conductive film is formed on the dielectric layer 17 and in the contact hole Hc, and is patterned by a known photolithography process (seventh photolithography step). The patterning is performed by wet etching. As a result, the common electrode CE is formed in the display region, and the island-shaped transparent connection portion 15sg that is in contact with the gate connection portion 3sg and the source connection portion 8sg is formed in the S-G connection portion forming region 201. The common electrode CE has a notch or slit for each pixel. In addition, the upper conductive portion 15t covering the lower conductive portion 3t is formed in the terminal forming region 203. Examples of the transparent conductive film include an indium tin oxide (ITO) film, IZO film, and zinc oxide (ZnO) film. Here, as the transparent conductive film, an ITO film (thickness: 100 nm) is used.

Next, as shown in FIG. 4G, the auxiliary metal interconnect 20 is formed that is in contact with the common electrode CE. The auxiliary metal interconnect 20 is formed by, for example, forming a metal film such as a Cu film (thickness: 200 nm) on the transparent conductive layer, and patterning the metal film by a known photolithography process (eighth photolithography step). Note that the auxiliary metal interconnect 20, which is in contact with the common electrode CE, may be disposed closer to the substrate 1 than the common electrode CE is. Thus, the TFT substrate 100 is produced.

In the above method, the resistance of the pixel-electrode-forming oxide semiconductor layer 7a is reduced using the dielectric layer 17, or alternatively, can be reduced by other techniques such as a plasma treatment. For example, after the fifth photolithography step, a resistance reduction treatment such as a plasma treatment may be performed before the dielectric layer 17 is formed.

Specifically, after the pixel opening 11p is formed in the interlayer insulating layer 11, the substrate 1 is exposed to a reducing plasma or a plasma containing a doping element (resistance reduction treatment). Here, the substrate 1 is exposed to an argon plasma, which is a reducing plasma. As a result, the resistance of a portion of the pixel-electrode-forming oxide semiconductor layer 7a that is exposed through the pixel opening 11p is reduced in the vicinity of the surface, so that the portion is changed to the low-resistance region 70d. A portion of the pixel-electrode-forming oxide semiconductor layer 7a that is masked by the interlayer insulating layer 11 and remains unchanged (i.e., the resistance of the portion has not been reduced) serves as the semiconductor region 70s. Although the thickness of the low-resistance region 70d may vary depending on the conditions of the resistance reduction treatment, the low-resistance region 70d is preferably made conductive across the thickness in the thickness direction of the pixel-electrode-forming oxide semiconductor layer 7a. Thereafter, the dielectric layer 17 is formed. In this case, the dielectric layer 17 may not be a reducing insulating film. Note that the method and conditions for the resistance reduction treatment are not limited to those described above.

### Variations

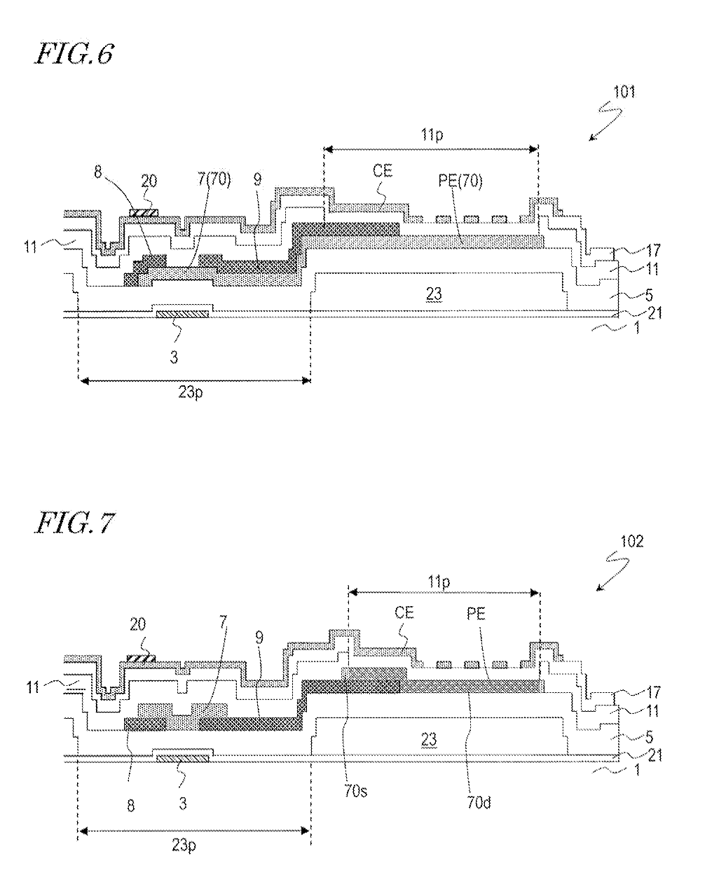

FIGS. 6 and 7 are cross-sectional views showing pixel regions P of other TFT substrates 101 and 102, respectively, of this embodiment. In these figures, parts similar to those of FIG. 3 are indicated by the same reference characters. Differences from the TFT substrate 101 of FIG. 3 will be mainly described.

In the TFT substrate 101, the oxide semiconductor layer 7 and the pixel electrode PE are integrally formed and continuous. As used herein, a layer 70 including the oxide semiconductor layer 7 and the pixel electrode PE is referred to as a “metal oxide layer.” The metal oxide layer 70 includes a low-resistance region that functions as the pixel electrode PE, and a semiconductor region that functions as the active layer of the TFT 10. The TFT substrate 101 can be produced using a method that is similar to that for the TFT substrate 100, except for the shape of a mask for patterning the oxide semiconductor film.

In the TFT substrate 102, the TFT 10 has a bottom-contact structure in which a lower surface of the oxide semiconductor layer 7 is in contact with the source and drain electrodes. The TFT substrate 102 can be produced using a method that is similar to that for the TFT substrate 100, except that the oxide semiconductor film is formed and patterned after the source metal layer is formed. In the TFT substrate 102, a peripheral portion of the island-shaped pixel electrode PE may serve as a semiconductor region 70s covered by the interlayer insulating layer 11, and a center portion of the island-shaped pixel electrode PE may serve as a low-resistance region 70d. The low-resistance region 70d may be surrounded by the semiconductor region 70s as viewed in the normal direction of the substrate 1.

In the case of the TFT substrate 102, the source-drain separation process is performed before the oxide semiconductor film is formed, and therefore, the TFT 10 can be formed without damage to a region of the oxide semiconductor layer 7 to become a channel. Therefore, characteristics and reliability of the TFT 10 can be improved.

### TFT Structure and Oxide Semiconductor

The TFT 10 may be a channel etch-type TFT or an etch stop-type TFT. In the “channel etch-type TFT,” as shown in, for example, FIGS. 2A and 2B, an etch-stop layer is not formed on the channel region, and a lower surface of an end closer to the channel of each of the source and drain electrodes is disposed in contact with an upper surface of the oxide semiconductor layer. The channel etch-type TFT is formed by, for example, forming a conductive film for source and drain electrodes on the oxide semiconductor layer, and separating the conductive film into a source and a drain. In the source-drain separation process, a surface portion of the channel region may be etched. Meanwhile, in the case of a TFT in which an etch-stop layer is formed on the channel region (etch stop-type TFT), a lower surface of an end closer to the channel of each of the source and drain electrodes is located on the etch-stop layer, for example. The etch stop-type TFT is formed by, for example, forming an etch-stop layer that covers a region of the oxide semiconductor layer to become the channel region, forming a conductive film for source and drain electrodes on the oxide semiconductor layer and the etch-stop layer, and separating the conductive film into a source and a drain. Note that in this case, the formation of the etch-stop layer requires an additional photolithography step.

The oxide semiconductor of the oxide semiconductor layer 7 may be an amorphous oxide semiconductor or a crystalline oxide semiconductor having a crystalline portion. Examples of the crystalline oxide semiconductor include polycrystalline oxide semiconductors, microcrystalline oxide semiconductors, and crystalline oxide semiconductors whose c-axis is oriented substantially perpendicularly to the layer surface.

The oxide semiconductor layer 7 may have a multilayer structure including two or more layers. In the case where the oxide semiconductor layer 7 has a multilayer structure, the oxide semiconductor layer 7 may include an amorphous oxide semiconductor layer and a crystalline oxide semiconductor layer. Alternatively, the oxide semiconductor layer 7 may include a plurality of crystalline oxide semiconductor layers having different crystal structures. Alternatively, the oxide semiconductor layer 7 may include a plurality of amorphous oxide semiconductor layers. In the case where the oxide semiconductor layer 7 has a two-layer structure including an upper layer and a lower layer, it is preferable that the energy gap of an oxide semiconductor contained in the upper layer be greater than the energy gap of an oxide semiconductor contained in the lower layer. Note that if the difference in energy gap between the upper and lower layers is relatively small, the energy gap of the oxide semiconductor contained of the lower layer may be greater than the energy gap of the oxide semiconductor of the upper layer.

Materials, structures, and film formation methods for amorphous oxide semiconductors and the above crystalline oxide semiconductors, and the configuration of the oxide semiconductor layer having a multilayer structure, etc., are described in, for example, Japanese Laid-Open Patent Publication No. 2014-007399, the entire contents of which are hereby incorporated by reference.

The oxide semiconductor layer 7 may, for example, contain at least one metal element of In, Ga, and Zn. In this embodiment, the oxide semiconductor layer 7 may contain, for example, an In—Ga—Zn—O semiconductor (e.g., indium gallium zinc oxide). Here, the In—Ga—Zn—O semiconductor is a ternary oxide of In (indium), Ga (gallium), and Zn (zinc). The proportions (composition ratio) of In, Ga, and Zn in the In—Ga—Zn—O semiconductor are not particularly limited. Examples of the composition ratio include In:Ga:Zn=2:2:1, In:Ga:Zn=1:1:1, and In:Ga:Zn=1:1:2. The oxide semiconductor layer 7 may be formed of an oxide semiconductor film containing the In—Ga—Zn—O semiconductor.

The In—Ga—Zn—O semiconductor may be either amorphous or crystalline. The crystalline In—Ga—Zn—O semiconductor is preferably one whose c-axis is oriented substantially perpendicularly to the layer surface.

Note that the crystal structure of the crystalline In—Ga—Zn—O semiconductor is described in, for example, Japanese Laid-Open Patent Publication No. 2014-007399 above, Japanese Laid-Open Patent Publication No. 2012-134475, Japanese Laid-Open Patent Publication No. 2014-209727, etc. The entire contents of Japanese Laid-Open Patent Publication Nos. 2012-134475 and 2014-209727 are hereby incorporated by reference. A TFT having the In—Ga—Zn—O semiconductor layer has a high mobility (more than 20 times as high as that of an a-SiTFT) and a low leakage current (less than one hundredth of that of an a-SiTFT), and therefore, is preferably used as a drive TFT (e.g., a TFT included in a drive circuit provided on the same substrate on which a display region including a plurality of pixels is provided, around the display region) and a pixel TFT (a TFT provided at a pixel).

The oxide semiconductor layer 7 may contain other oxide semiconductors instead of the In—Ga—Zn—O semiconductor. For example, the oxide semiconductor layer may contain an In—Sn—Zn—O semiconductor (e.g., In₂O₃—SnO₂—ZnO; InSnZnO). The In—Sn—Zn—O semiconductor is a ternary oxide of In (indium), Sn (tin), and Zn (zinc). Alternatively, the oxide semiconductor layer may contain In—Al—Zn—O semiconductors, In—Al—Sn—Zn—O semiconductors, Zn—O semiconductors, In—Zn—O semiconductors, Zn—Ti—O semiconductors, Cd—Ge—O semiconductors, Cd—Pb—0 semiconductors, CaO (cadmium oxide), Mg—Zn—O semiconductors, In—Ga—Sn—O semiconductors, In—Ga—O semiconductors, Zr—In—Zn—O semiconductors, Hf—In—Zn—O semiconductors, Al—Ga—Zn—O semiconductors, Ga—Zn—O semiconductors, In—Ga—Zn—Sn—O semiconductors, etc.

Note that the pixel electrode PE may have the same composition and crystalline structure as those of the oxide semiconductor layer 7. In the case where the oxide semiconductor layer 7 has a multilayer structure, the pixel electrode PE may have a multilayer structure similar to that of the oxide semiconductor layer 7.

The active matrix substrate of the embodiment of the present invention is widely applicable to display apparatuses, such as liquid crystal display apparatuses, organic electroluminescent (EL) display apparatuses, and inorganic electroluminescent display apparatuses, image capture apparatuses, such as image sensor apparatuses, electronic apparatuses, such as image input apparatuses and fingerprint reading apparatuses, etc.

This application is based on Japanese Patent Applications No. 2017-205022 filed on Oct. 24, 2017, the entire contents of which are hereby incorporated by reference.

What is claimed is:

1. An active matrix substrate having a display region including a plurality of pixel regions, and a non-display region that is different from the display region, comprising:
a substrate;
a plurality of source bus lines supported by the substrate and extending in a first direction;
a plurality of gate bus lines supported by the substrate and extending in a second direction crossing the first direction;
a thin-film transistor disposed in each of the plurality of pixel regions;
a pixel electrode disposed in each of the plurality of pixel regions;
a common electrode disposed on the pixel electrode with a dielectric layer interposed therebetween; and
a spin-on-glass layer disposed, in the display region, between a gate metal layer including the plurality of gate bus lines, and a source metal layer including the plurality of source bus lines, wherein
in each of the plurality of pixel regions, the thin-film transistor has a gate electrode formed in the gate metal layer, a gate insulating layer covering the gate electrode, an oxide semiconductor layer disposed on the gate insulating layer, and a source electrode and a drain electrode formed in the source metal layer and electrically connected to the oxide semiconductor layer, the gate electrode is electrically connected to a corresponding one of the plurality of gate bus lines, the source electrode is electrically connected to a corresponding one of the plurality of source bus lines, and the drain electrode is in contact with the pixel electrode,
the pixel electrode is formed of a same metal oxide film of which the oxide semiconductor layer is formed,
the spin-on-glass layer has an opening in a portion thereof in which the thin-film transistor is formed, in each of the plurality of pixel regions, and
at an intersection portions where the corresponding one of the plurality of source bus lines and the corresponding one of the plurality of gate bus lines intersect, the spin-on-glass layer is located between the corresponding one of the plurality of source bus lines and the corresponding one of the plurality of gate bus lines, and in each of the plurality of pixel regions, the spin-on-glass layer is located between at least a portion of the pixel electrode and the substrate.

2. The active matrix substrate of claim 1, wherein
the pixel electrode and the oxide semiconductor layer are disposed apart from each other, and
the entire pixel electrode overlaps with the spin-on-glass layer as viewed in a normal direction of the substrate,
and the oxide semiconductor layer is located in the opening of the spin-on-glass layer.

3. The active matrix substrate of claim 1, wherein
the pixel electrode is continuous with the oxide semiconductor layer.

4. The active matrix substrate of claim 1, further comprising:
an auxiliary metal interconnect in contact with the common electrode.

5. The active matrix substrate of claim 4, further comprising:
an inorganic insulating layer disposed between the source metal layer and the dielectric layer, wherein
the pixel electrode includes a first portion that is in contact with the inorganic insulating layer, and a second portion that is in contact with the dielectric layer, and
the first portion is a semiconductor region, and the second portion is a low-resistance region having an electrical resistivity lower than that of the semiconductor region.

6. The active matrix substrate of claim 5, wherein
the dielectric layer contains silicon nitride, and the inorganic insulating layer contains silicon oxide.

7. The active matrix substrate of claim 1, wherein
the gate insulating layer includes a first insulating layer, and a second insulating layer disposed between the first insulating layer and the gate electrode, and
the spin-on-glass layer is disposed between the second insulating layer and the first insulating layer.

8. The active matrix substrate of claim 1, wherein
the drain electrode is in contact with upper surfaces of the oxide semiconductor layer and the pixel electrode.

9. The active matrix substrate of claim 1, wherein
the drain electrode is in contact with lower surfaces of the oxide semiconductor layer and the pixel electrode.

10. The active matrix substrate of claim 1, wherein
the oxide semiconductor layer contains an In—Ga—Zn—O semiconductor.

11. The active matrix substrate of claim 10, wherein
the In—Ga—Zn—O semiconductor includes a crystalline portion.

12. The active matrix substrate of claim 1, wherein
the oxide semiconductor layer of the thin-film transistor has a multilayer structure.

13. A method for producing an active matrix substrate having a display region including a plurality of pixel regions, and a non-display region that is different from the display region, and including a thin-film transistor and a pixel electrode disposed in each of the plurality of pixel regions, the method comprising:
(a) forming, on the substrate, a gate metal layer including gate electrode of the thin-film transistor in each of the plurality of pixel regions and a plurality of gate bus lines;
(b) forming a spin-on-glass layer by forming a spin-on-glass film on the gate metal layer, and forming, in each of the plurality of pixel regions, an opening in a portion of the spin-on-glass film where the thin-film transistor is subsequently formed;
(c) forming a first insulating layer on the spin-on-glass layer;
(d) forming an oxide semiconductor film on the first insulating layer and patterning the oxide semiconductor film so as to form an active-layer-forming oxide semiconductor layer and a pixel-electrode-forming oxide semiconductor layer, the active-layer-forming oxide semiconductor layer being to become an active layer of the thin-film transistor, the pixel-electrode-forming oxide semiconductor layer being to become the pixel electrode, wherein the active-layer-forming oxide semiconductor layer is disposed so that, in the opening of the spin-on-glass layer, at least a portion thereof overlaps with the gate electrode with the first insulating layer interposed therebetween, and the pixel-electrode-forming oxide semiconductor layer is disposed on the spin-on-glass layer with the first insulating layer interposed therebetween;
(e) forming a source metal layer including source electrode and drain electrode of the thin-film transistor in each of the plurality of pixel regions and a plurality of source bus lines, wherein the source electrode is in contact with the active-layer-forming oxide semiconductor layer, and the drain electrode is in contact with the active-layer-forming oxide semiconductor layer and the pixel-electrode-forming oxide semiconductor layer;
(f) forming an inorganic insulating layer covering the active-layer-forming oxide semiconductor layer, the pixel-electrode-forming oxide semiconductor layer, the source electrode and the drain electrode, and forming a pixel opening, in the inorganic insulating layer, through which a portion of the pixel-electrode-forming oxide semiconductor layer is exposed;
(g) forming a dielectric layer on the inorganic insulating layer and in the pixel opening, the dielectric layer having ability to reduce an oxide semiconductor contained in the pixel-electrode-forming oxide semiconductor layer, wherein the resistance of a portion of the pixel-electrode-forming oxide semiconductor layer that is in contact with the dielectric layer in the pixel opening is reduced so that the portion becomes a low-resistance region functioning as the pixel electrode, and a portion of the pixel-electrode-forming oxide semiconductor layer that is covered by the inorganic insulating layer remains as a semiconductor region; and
(h) forming a common electrode on the dielectric layer.

14. The method of claim 13, wherein
in step (d), the active-layer-forming oxide semiconductor layer and the pixel-electrode-forming oxide semiconductor layer are spaced apart from each other, the entire active-layer-forming oxide semiconductor layer is located in the opening of the spin-on-glass layer, and the entire pixel-electrode-forming oxide semiconductor layer is disposed on the spin-on-glass layer with the first insulating layer interposed therebetween.

15. The method of claim 13, further comprising:
forming an auxiliary metal interconnect that is in contact with the common electrode.

16. The method of claim 13, wherein
the oxide semiconductor film contains an In—Ga—Zn—O semiconductor.

17. The method of claim 16, wherein
the In—Ga—Zn—O semiconductor includes a crystalline portion.

18. The method of claim 13, wherein
the oxide semiconductor film has a multilayer structure.
